(19) United States
(12) Patent Application Publication
(10) Pub. No.: US 2002/0022310 A1
(43) Pub. Date: Feb. 21, 2002

(54) Epoxy-polyimide composites suitable as encapsulants

(76) Inventors: Haksoo Han, Seoul (KR); Won Bong Jang, Seoul (KR); Hyun Soo Chung, Goyang (KR); Jong Hwae Lee, Seoul (KR)

Correspondence Address: Shanks & Herbert, TransPotomac Plaza, Suite 306, 1033 N. Fairfax Street, Alexandria, VA, 22314, US

(21) Appl. No.: 09/839,749

(22) Filed: Apr. 23, 2001

(30) Foreign Application Priority Data
Jul. 7, 2000 (KR) 2000-38797

(51) Int. Cl. H01L 21/8238

(52) U.S. Cl. 438/200

(57) ABSTRACT

This invention provides novel epoxy-polyimide composites and process for producing the same which has excellent thermal stability and mechanical properties whereby soluble reactive polyimide containing hydroxyl functional group were used as a curing agent. The novel epoxy-polyimide composites, which is polymerized by reacting epoxy resin and polyimide during curing process, can be widely used as insulating intermediate layer in integrated circuits and electronic circuit encapsulants. The invention also provides an epoxy resin/polyimide composition comprising an epoxy resin and a polyimide.

### BACKGROUND OF THE INVENTION

1. Field of the invention

This invention relates to epoxy-polyimide composites and to a process for producing them. The composites are suitable for the film type encapsulation of electronic and semiconductor devices.

2. Description of the Related Art

As the development of semiconductor devices shows a trend toward higher density, surface mount packages have now become the mainstream in semiconductor technology. Among them advanced composite materials, surface coatings and electronic circuit encapsulants are examples of applications involving the cure of a thermoset material in contact with a solid substrate. In such processes the shrinkage of the polymer will be partly constrained by the substrate, thereby generating stress at the interface between the polymer and the substrate. High stress levels may greatly reduce the technical performance of a system through cracking, interface debonding and dimensional instability. In particular, packages encapsulated with conventional encapsulants have the problem that reliability is not ensured because cracks are generated in the encapsulant portion during mounting.

Epoxy resins are usually used for the encapsulation of electronic and semiconductor devices because of their excellent physical properties after curing and ease in handling. Epoxy resins are a versatile group of cross-linked polymers that have excellent chemical resistance, good electrical insulation properties, good adhesion to glass and good plasticity. The above mentioned properties help the epoxy resins to meet the demanding requirements of technical fields, such as construction, electronics, adhesives and coatings (Y. Nakamura, N. M. Yamaguchi, A. Tanaka and M. Ocubo, “Journal of Applied Polymer Science”, vol.49, p.331 (1993)). However the applicability of epoxy resins is often limited due to their inherent brittleness resulting from their cross-linked structure. Therefore, if moisture penetrates into the circuit plate encapsulated by such epoxy resins, the insulating function of the electronic elements and its packaging get harmed resulting in malfunctioning and cracks.

Toughening epoxy resins without sacrificing Young's modulus and glass temperature would lead to their wider applicability. There have been many attempts to toughen epoxy resins by using organic rubbers as toughening additives (D. F. Bergstrom, G. T. Burns, G. T. Decker, R. L. Durall, D. Fryear, G. A. Gmowicz, M. Tokunoh and N. Odagiri, “Material Res. Soc. Symp. Proc.”, vol.31, p.274(1992)). While rubbers can be extremely effective as toughening agents, sun[??] rubber toughened epoxy resins still suffer from some drawbacks such as reduction in overall resin modulus and end use temperatures. As alternative methods, poly(ethersulfone) (C. B. Bucnall and I. K. Partridge, “Polymer”, vol.24, p.639 (1983)), poly(phenylenether) (R. S. Bauer, H. D. Stenzenberger and W. Romer, “35^{th} Int. SAMPE Symp.”, p.395 (1990)), poly(etherketone) (G. S. Bennett, R. J. Farris and S. A. Thompson, “Polymer”, vol.32, p.1633 (1991)), polyester (T. Iijima, T. Tochimoto, M. Tomoi and H. Kakiuchi, “Journal of Applied Polymer Science”, vol.43, p.463 (1991)) and poly(etherimide) (N. Biolly, T. Pascal and B. Sillion, “Polymer”, vol.35, p.558 (1994)) have been used as thermoplastic toughening agents.

Among them polyimides have been frequently used as protective overcoats and dielectric layers for semiconductor devices because of their good properties, for example, excellent thermal stability, high chemical resistance, good mechanical properties, low dielectric constant and easy processability (H. Chung, Y. Joe and H. Han, “Polymer Journal”, vol.31, p.700 (1999)). The use of polyimides in epoxy systems to improve thermal resistance and moldability is also disclosed in U.S. Pat. Nos. 4,808,676 and 4,948,831. But these efforts have been mainly focused on and limited to the mechanical blending of unreactive linear polyimides (J. N. Hay, B. Woodfine and M. Davies, “High Performance Polymer”, vol.8, p.35 (1996)). Thus continuous efforts are being made to develop novel insulating surface coatings and electronic circuit encapsulants that can solve the above-mentioned problems.

A portion of this invention was disclosed in “Theories and Applications of Chem. Eng.”, vol.6, no.1, p.2201(2000) published in Apr. 21, 2000, the content of which is incorporated hereinto by reference.

### SUMMARY OF THE INVENTION

Accordingly, the present invention provides compounds, as well as processes for preparing these compounds, that solve these and other longstanding problems in the art.

Thus, the invention provides epoxy-polyimide composites with excellent thermal stability and mechanical properties. The novel epoxy-polyimide composites have a repeating unit represented by general formula 1-a or 1-b.

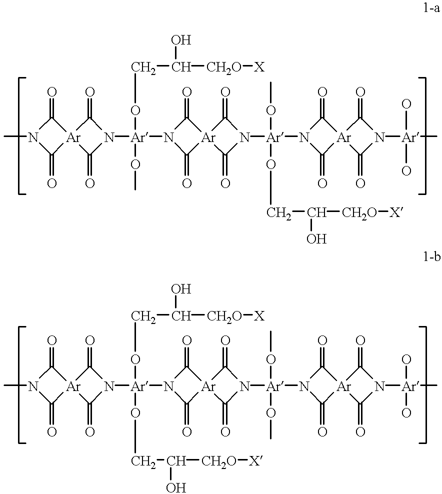

wherein

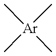

is an aromatic group selected from the group consisting of:

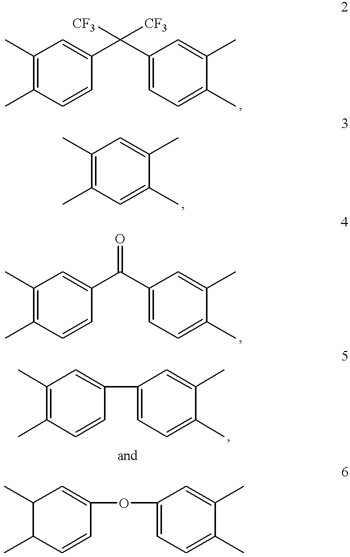

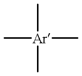

is an aromatic group of the general formula 7

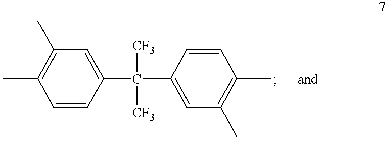

X and X′ are independently an epoxy moiety.

This epoxy-polyimide composite can be widely used as an insulating intermediate layer and encapsulant, for example in the semiconductor fabrication process.

The present invention also provides a polyimide having a repeating unit of the following formula 12:

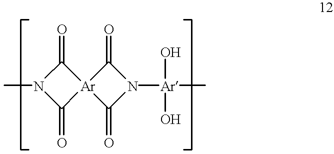

wherein,

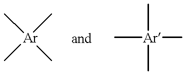

have the same meanings as defined above.

The invention also provides a composition comprising an epoxy resin and a polyimide, wherein said polyimide has a repeating unit of the general formula 12.

The present invention also provides a novel process for preparing epoxy-polyimide composites of formula 1.

The present invention further provides a use of the epoxy-polyimide composition in encapsulating electronic elements.

### BRIEF DESCRIPTION OF THE DRAWINGS

FIG. 1 illustrates the conditions for the curing process for producing polyimide powder.

FIG. 2 illustrates the FT-IR graph verifying the completion of polyimide formation process using thermal imidization.

FIG. 3 illustrates one embodiment of the conditions employed for the curing of epoxy resin/polyimide composition to form a film.

FIG. 4 is the Thin Film Stress Analyzer which is used to measure the real time stress behavior between the formed film and silicon wafer in Example 5. In FIG. 4, the numerical number 18 indicates a laser, 19 a beam splitter, 20 a mirror, 21 the film formed on the silicon wafer 22, and 23 detector.

FIG. 5 shows the stress behavior results measured by the Thin Film Stress Analyzer as shown in FIG. 4.

FIG. 6 shows the Differential Scanning Calorimeter (DSC) results for the epoxy films formed from the expoy/polyimide composite of the present invention by the curing process.

### DETAILED DESCRIPTION OF THE INVENTION

Accordingly, novel epoxy-polyimide composites suitable for use as an insulating intermediate layer in integrated circuits and electronic circuit encapsulants as well as a process for producing those polymers are provided.

And a novel epoxy resin/polyimide composition comprised of an epoxy resin and polyimide is provided.

The novel epoxy-polyimide composites of the present invention have a repeating unit represented by the general formula 1-a or 1-b.

Several terms used throughout the application are defined as follows.

The term “soluble” refers that the material such as polyimide is completely soluble in organic solvents such as acetone, N-methylpyrrolidone, N-N-dimethyl acetanide and dimethyl formamide. Generally, polyimide is non-soluble in organic solvents, but the polyimide of the present invention is completely soluble in the above mentioned solvents.

The term “epoxy-polyimide composite” or “composite” refers to polymers formed by cross-linking between the polyimide and epoxy resins or epoxides.

The term “epoxy resin/polyimide composition,” “epoxy/polyimide composition,” or “composition” refers to a mixture of an epoxy resin or epoxides, and a polyimide.

The term “epoxy resin” refers to any resins based on the epoxides; and the term “epoxides” refers to any organic compound with a reactive group consisting of an oxygen atom bonded to two adjacent carbon atoms that are bonded together. In the application, the term “epoxy resin” is used to include epoxy resins and epoxides. For the present invention, the epoxy resins that can be used preferably have an excellent molding property, and include novolak type epoxy resins, cresol novolak type epoxy resins, biphenyl type epoxy resins, triphenol alkane type epoxy resins, heteroglycidic epoxy resins, bisphenol A type epoxy resins, bisphenol F type epoxy resins, naphthalene ring-containing type epoxy resins. In the general formulae 1-a and 1-b, the term “epoxy moiety” refers to the moiety of the epoxy resins except the epoxide part

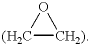

Among the epoxy resins, those which may be preferably used in the present invention include, but are not limited to, cresol novolak type epoxy resins, biphenyl type epoxy resins, bisphenol A type epoxy resin and naphthalene ring-containing type epoxy resin which may be represented by formulae 8, 9, 10 and 11, respectively.

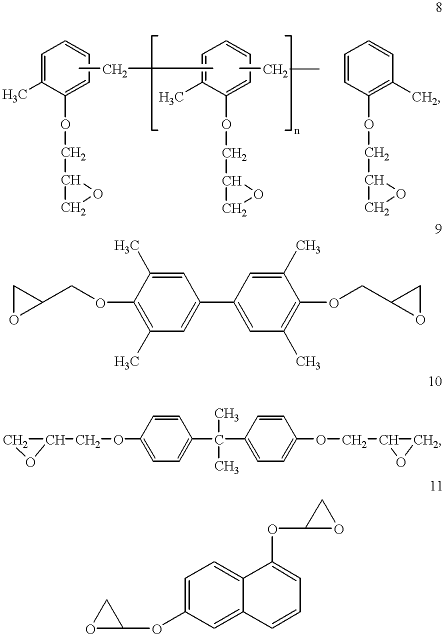

The polyimide preferably has excellent stress resistance, insulation and low moisture absorption properties. The polyimide of the invention is a novel compound and has a repeating unit represented by general formula 12 or 12′:

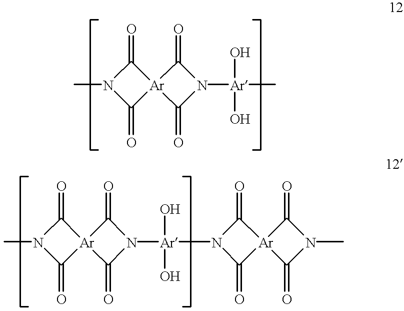

wherein

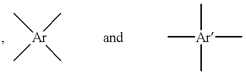

are defined as above.

The polyimide of the present invention may have an average molecular weight ranging from 10,000 to 30,000.

In the present invention, polyimides having hydroxyl groups are advantageously used. For example, an aromatic polyimide containing pendent hydroxyl groups ortho to the heterocyclic imide nitrogen is rearranged to 2,2-bis(3,4-dicarboxyphenyl)hexafluoropropane upon heating above 220° C. in an inert atmosphere. A hydroxyl functional group containing fully aromatic polyimide film based on 2,2-bis(3,4-dicarboxyphenyl)hexafluoropropane (6FDA) and 2,2-bis(3-amino-4-hydroxyphenyl)-hexafluoropropane (AHHFP) was prepared by thermal curing and then reacted with biphenyl epoxy resin. The resulting film was found to be amorphous by wide angle X-ray diffraction (WAXD). The film also showed excellent solvent resistance and good thermal stability by Differential Scanning Calorimeter (DSC) in nitrogen at 500° C.

The liquid-state epoxy resin alone shrinks after applying on the articles such as electronic parts to be coated because of the surface tension of the epoxide ring at the end terminals. In order to prevent shrinkage, a polyimide having hydroxyl groups that can form a chemical bond to the ring-opened epoxide ring is used in this invention. Moreover, by introducing fluorine-containing type functional substituents into the polyimide chain, capability of film formation and stress resistance, insulation and low moisture absorption properties are improved. Furthermore, by crosslinking the polyimide with the epoxy resins, there is no need to use separate curing agents for the manufacture of film type packages and encapsulants. Therefore this novel epoxy-polyimide composite is suitable for film type encapsulation of electronic and semiconductor devices.

The process for the manufacture of the novel epoxy-polyimide composites is explained below.

Step 1: Preparation of liquid polyamic acid

Diamine (1-5 mmol), represented by general formula 13, like 2,2′-bis(3-amino-4-hydroxyphenyl)-hexafluoropropane,

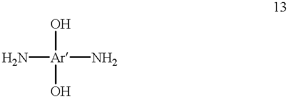

wherein

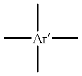

is defined as above, is placed in a flask with a nitrogen inlet and a mechanical stirrer, and dissolved completely in 10-100 ml of organic solvent under nitrogen. As organic solvent N-methylpyrrolidone (NMP), acetone, N,N-dimethyl acetaride or dimethyl formamide can be used. 1-10 mmol of dianhydride monomer, which may be represented by formula 14:

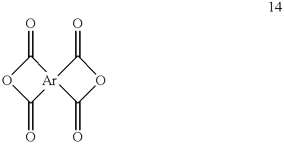

wherein

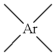

is defined as above, and 5-15 ml of the above mentioned organic solvent are added to the solution and are incubated under nitrogen. As the dianhydride monomer, 4,4′-(hexafluoroisopropylidene) diphthalic acid dianhydride monomer, pyromelite acid dianhydride monomer, 3,3′,4,4′-benzophenon tetracarboxylic acid dianhydride monomer, 3,3′,4,4′-biphenyl tetracarboxylic dianhydride monomer, or 4,4′-oxy diphthalic acid dianhydride monomer can be used. After 12-48 hr incubation with constant stirring at room temperature, the reaction mixture comprising the viscous polyamic acid is obtained. The polyamic acid thus obtained has a repeating unit that is represented by the general formula 15.

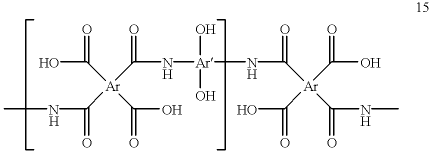

As a dianhydride monomer, tetracarboxylic acid dianhydride which is used commonly in polyimide preparation processes may be employed. And if the tetracarboxylic acid dianhydride is located around the aromatic group “Ar”, thermal resistance of the resulting polyimide can be greatly improved.

Step 2: Preparation of polyamic acid powder

After the reaction of step 1 is completed, the polyamic acid is precipitated in distilled water by slowly adding the resulting mixture to the water. The precipitate is filtered, washed with water (e.g., distilled water), filtered again under the pressure condition of 5-20 mmHg.

Step 3: Preparation of polyimide

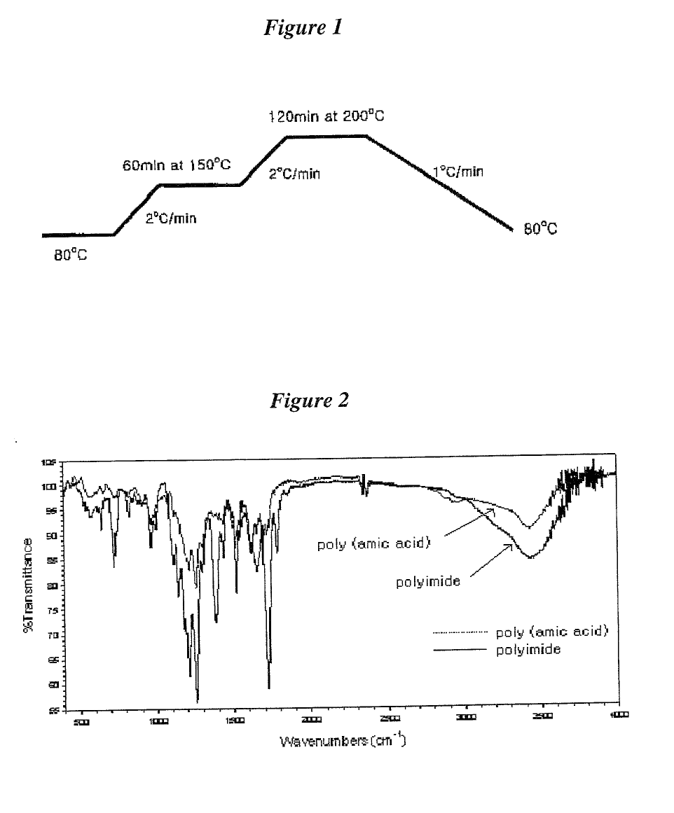

The polyamic acid powder prepared in step 2 is transformed into polyimide powder by thermal imidization (“curing process”). The curing process is as follows: maintaining for about 20-40 min at about 60-100° C., heating to raise the temperature at a rate of about 1-4° C./min until a temperature of about 120-180° C. is attained, annealing for about 30-80 min at about 120-180° C., heating to raise the temperature at a rate of about 1-4° C/min until a temperature of about 180-220° C. is attained, annealing about 90-150 min at about 180-220° C. and cooling to lower the temperature at a rate of about 1-4° C./min until a temperature of about 60-100° C. is attained. One embodiment of the curing process has the conditions as depicted in FIG. 1. A yellow polyimide powder is obtained after solvent evaporation. The polyimide thus obtained has an identical chemical structure with that of the liquid polyamic acid.

The polyimide thus obtained in the powder form has the repeating unit of formula 12. The polyimide powder shows good solubility in organic solvents such as acetone, N,N-dimethylacetamide, N-methylpyrrolidinone or dimethylformamide. In order to dissolve polyimide with epoxy resins in solvents, polyimide is advantageously prepared in the powder form.

The repeating unit of the polyimide represented by formula 12 can have different structures according to the combination of dianhydride monomer (formula 14) and diamine (formula 13), and also its physical properties can be changed and controlled by the combination of dianhydride monomer and diamine selected. For example, the polyimides having an aromatic group

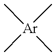

with linkages such as —O— or an optionally substituted —CH₂— in the molecule like that of formulae 2, 4 and 6 are preferred because they enhance solubility and flexibility of the composite.

Step 4: Preparation of liquid epoxy/polyimide composition

Epoxy resins in the form of powder are completely dissolved in an organic solvent under nitrogen. As an organic solvent, N-methylpyrrolidone, acetone, N,N-dimethyl acetamide or dimethyl formamide can be used. The powder form of the polyimide with hydroxyl groups of step 3 is added to the solution to prepare the liquid epoxy-polyimide composition.

The epoxy resins used must have excellent molding property and preferably are selected from novolak type epoxy resins, cresol novolak type epoxy resins, biphenyl type epoxy resins, triphenol alkane type epoxy resins, heteroglycidic epoxy resins, bisphenol A type epoxy resins, bisphenol F type epoxy resins, naphthalene ring-containing type epoxy resins. Of these, preferred are cresol novolak type epoxy resins, biphenyl type epoxy resins, bisphenol A type epoxy resins or naphthalene ring-containing type epoxy resins. Therefore, by the combination of the polyimide prepared in step 3 and the epoxy resins, various structures of epoxy-polyimide composites can be obtained whose physical properties can be changed and controlled by adjusting this combination. For example, epoxy resins of formula 8 with more than 3 epoxide rings, offer more reaction sites than those with two or less epoxide rings resulting in higher crosslinking density thereby improving the rigidity of the final product.

The concentration of the solution is preferably adjusted to 10-50% by weight. As described above, different solutions can be prepared with different weight ratios of the two components, epoxy resins and polyimides. The hydroxyl groups in polyimide are responsible for the bond to the ring-opened epoxide ring, therefore preventing the epoxy resins from shrinking during the film coating, encapsulating, or packaging process.

As described above, the epoxy-polyimide composites of the present invention can be applied to electronic devices and semiconductor devices for coating or packaging to form films or encapsulants. Namely, the liquid epoxy resin/polyimide composition of this invention can be dunk-in on the surface which is to be spin coated or packaged to obtain the wafer package during the wafer process. This procedure is described in more detail as follows.

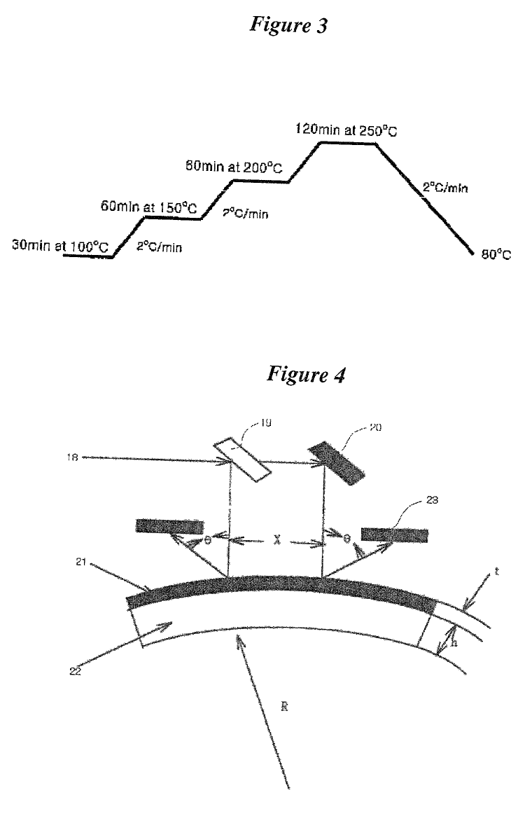

The liquid epoxy resin/polyimide composition is spin coated on the wafer at about 300-900 rpm and cured in a heat treatment oven under curing conditions to obtain film type package. The curing process is as follows: maintaining for about 20-40 min at about 80-120° C., heating with the rate of about 1-4° C./min until about 120-180° C. is attained, annealing about 30-90 min at about 120-180° C., heating to raise the temperature at a rate of about 1-4° C./min until a temperature of about 180-220° C. is attained, annealing about 30-90 min at about 180-220° C., heating to raise the temperature at a rate of about 1-4° C./min until a temperature of about 220-280° C. is attained, annealing about 90-150 min at about 220-280° C., and cooling to lower the temperature at a rate of about 1-4° C./min until a temperature of about 60-100° C. is attained. One embodiment of this curing process is shown in FIG. 3. The reaction during the curing process takes place by bond formation of polyamide and ring-opened epoxy resin to obtain epoxy-polyimide composites of formula 1, whereby the bond formation position varies according to the stoichiometric ratio. If the proportion of polyimide increases relative to that of epoxy resins, Young's modulus and glass transition temperature increase. Therefore the weight ratio can be easily varied to fit for the applications to be used. And as shown in reaction scheme 1, the hydroxyl groups of the epoxy resin moiety of the composite may further form a bond with the subsequent ring-opened epoxy resin.

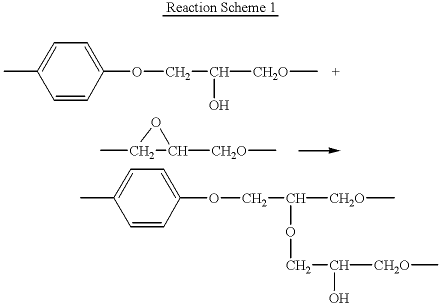

Thus, the composite of the present invention provides insulation materials which have not only excellent adhesive and molding properties, but also are electrically, mechanically, physically and chemically stable.

### EXAMPLES

Examples of the invention are given below by way of illustration and not by way of limitation.

In the examples, intrinsic viscosity, residual stress, and glass transition temperature were measured by conventional methods known to the person skilled in the art.

FT-IR Spectroscopy

The bands indicating conversion of polyamic acid into polyimide are 1776 cm⁻¹ (symmetric carbonyl stretch), 1380 cm¹ (stretching vibration of C-N, 725 cm⁻¹ (bending vibration of cyclic carbonyl group), and the absorption band of epoxide ring is 915 cm⁻ (stretching absorption of C—O). In order to identify the conversion of polyamic acid precursor into polyimide and to monitor the progress of epoxy-polyimide composite Genesis Series FT-IR (ATI Mattson Co.) was used. Measurements were performed at the frequency range of 400 to 4000 cm⁻¹, resolution of 0.2 cm⁻¹ and the scanning number was 16 times.

DSC

In order to identify the curing reaction of epoxy-polyimide composite differential scanning calorimetry (DSC, Polymer Laboratories) was used. Exothermal peaks resulting from curing process were identified with the rate of 10° C./min under nitrogen.

TGA

The change of thermal stability was measured according to the mass of epoxy resins/polyimide by using thermogravimetric analyzer (TGA, TA Instrument). The measuring was made at the rate of 10° C./min under nitrogen.

### Example 1

### Preparation of the Liquid Polyamic Acid

Diamine, 2,2′-bis(3-amino-4-hydroxyphenyl)-hexafluoropropane (“AHHFP”; 5 mmol), was placed in a flask with a nitrogen inlet and a mechanical stirrer, and dissolved completely in 40 ml of N-methylpyrrolidone under nitrogen to give a solution. 5 mmol of 4,4′-(hexafluoroisopropylidene) diphthalic acid dianhydride monomer (“6FDA”) and 8 ml of N-methylpyrrolidone were added to the solution and were incubated at room temperature under nitrogen. After 24 hr incubation with constant stirring at room temperature, the reaction mixture comprised of the viscous polyamic acid was obtained.

### Example 2

### Preparation of the Powder Polyamic Acid

After the reaction of Example 1 was completed, the liquid polyamic acid was precipitated in distilled water by slowly adding the solution into the water. The precipitate was filtered, washed with distilled water, filtered again under the reduced pressure condition of 10 mmHg. Polyamic acid was obtained as a white powder with a yield of 88.3%.

### Example 3

### Preparation of Polyimide

The polyamic acid powder was transformed into polyimide powder under curing conditions (FIG. 1) by thermal imidization. A yellow polyimide powder was obtained after solvent evaporation. The 6FDA/AHHFP polyimide thus obtained has a chemical structure identical to the liquid polyamic acid.

The imidization was confirmed through the peaks of 1780, 1380 and 725 cm⁻¹ in FT-IR analysis. (FIG. 2). The polyimide powder showed good solubility in organic solvents such as acetone, N,N-dimethylacetamide, N-methylpyrrolidinone or dimethylformarnide. The intrinsic viscosity measured at 30° C. in N-methylpyrrolidinone was 0.86 dl/g.

### Example 4

### Preparation of Liquid Epoxy Resin/Polyimide Composition

Biphenyl epoxy resin (4,4′-diglycidyloxy-3,3′,5,5′-tetramethyl biphenyl epoxy resin, Yuka Shell Epoxy Co.) in the form of powder was completely dissolved in N-methylpyrrolidinone (NMP) under nitrogen. The powder form of polyimide with hydroxyl groups of Example 3 was added to the solution to prepare liquid epoxy resin/polyimide composition. The concentration of the solution was adjusted to 30% by weight. As described in Table 1, different compositions were prepared with different weight ratios of the two components, epoxy resin and polyimide.

TABLE 1

| Composition | | | M:n | | Residual stress | Glass transition |
|---|---|---|---|---|---|---|
| (Figure No.) | Epoxy | Polyimide | (wt %) | Solvent | (Mpa) (25° C.) | temp. (° C.) |
| 5A | Biphenyl | 6FDA/AHHFP | 0:100 | NMP | 70 | 385 |
| 5B | Biphenyl | 6FDA/AHHFP | 40:60 | NMP | 60 | >220 |
| 5C | Biphenyl | 6FDA/AHHFP | 50:50 | NMP | 50 | 191 |
| 5D | Biphenyl | 6FDA/AHHFP | 60:40 | NMP | 46 | 155 |
| 5E | Biphenyl | 6FDA/AHHFP | 70:30 | NMP | 31 | 140 |
| 5F | Biphenyl | 6FDA/AHHFP | 85:15 | NMP | 18 | 108 |

### Example 5

### Preparation of the Film and Encapsulant

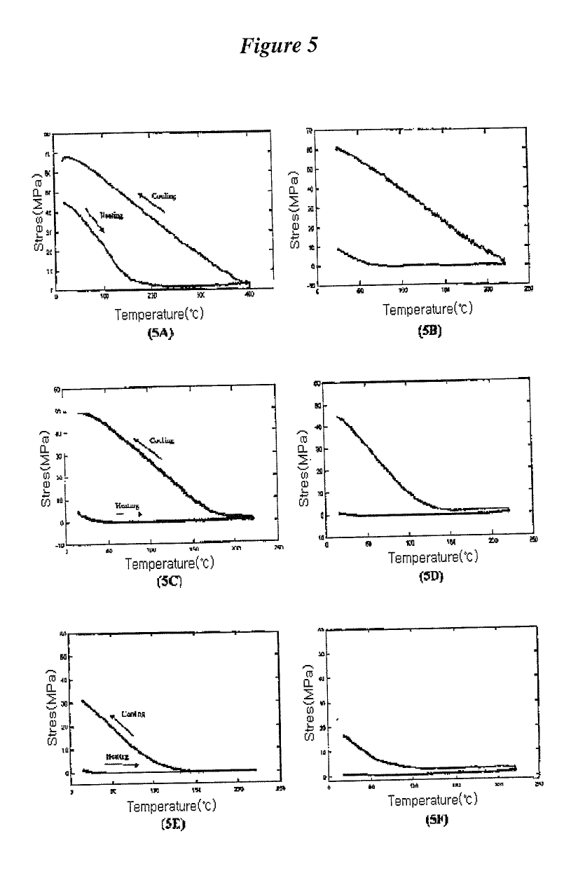

To use the liquid epoxy resin/polyimide compositions prepared in Example 4 for the spin coating of a wafer or dunk-in package, the liquid epoxy/polyimide composition was spin coated on the wafer at 600 rpm and cured in a heat treatment oven under curing conditions to obtain epoxy-polyimide composites (FIG. 3). The change of the stress between the film and the silicone wafer during film formation by curing was measured using the thin film stress analyzer as shown in FIG. 4 at real time scale. Glass transition temperature was also measured. The results are summarized in FIG. 5A through 5F, and Table 1.

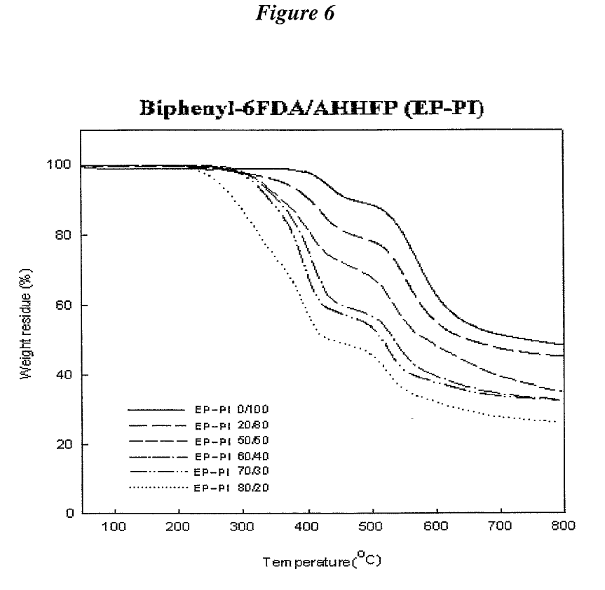

The epoxy film thereby produced had a transparent yellow color. The TGA (Thermogravimetric Analysis) results are presented in FIG. 6. The mass fraction ratio of epoxy resins to polyimide were 0:100, 20:80, 50:50, 60:40, 70:30, 80:20 and the curing process were performed at temperature of 220° C. As the mass fraction of polyimide was increased by 5 wt. % or 10 wt. % degradation temperature increased to a larger extent than that for pure epoxy resins. Therefore the epoxy-polyimide composite of this invention is suitable for use as encapsulants. The results are shown in Table 2.

TABLE 2

| | 5 wt. % Degradation | 10 wt. % degradation |
|---|---|---|
| Epoxy/Polyimide | temperature(° C.) | temperature(° C.) |
| 80:20 | 253 | 286 |
| 70:30 | 319 | 334 |
| 60:40 | 329 | 343 |
| 50:50 | 331 | 363 |
| 20:80 | 362 | 404 |
| 0:100 | 426 | 471 |

What is claimed is:

1. A polyimide having a repeating unit represented by the following formula: 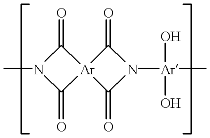
wherein 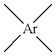
is an aromatic group selected from the group consisting of: 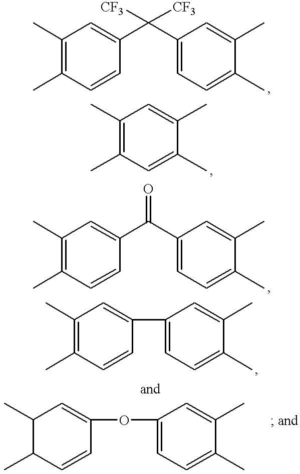 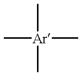
is an aromatic group of the general formula:

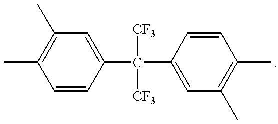

2. The polyimide of claim 1 having an average molecular weight ranging from 10,000 to 30,000.

3. The polyimide of claim 1 in which 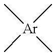
is selected from the group consisting of:

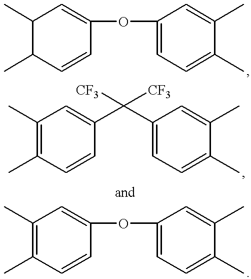

4. The polyimide of claim 1 which is soluble in an organic solvent.

5. The polyimide of claim 4 which is in the form of a powder.

6. A composition comprising an epoxy resin and polyimide, said polyimide having a repeating unit represented by the following formula: 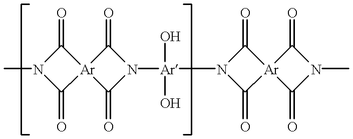
wherein 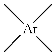
is an aromatic group selected from the group consisting of: 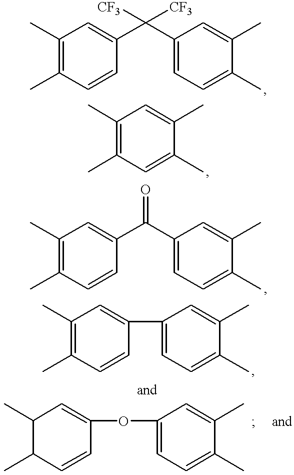 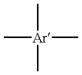
is an aromatic group of the general formula:

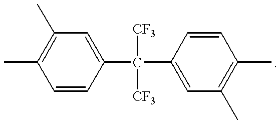

7. The composition of claim 6, in which said epoxy resin and said polyimide are dissolved in an organic solvent.

8. The composition of claim 7, in which said organic solvent is selected from the group consisting of N-methylpyrrollidone, acetone, N,N-dimethyl acetamide, and dimethylformamide.

9. The composition of claim 7, in which said epoxy resin is selected from the group consisting of novolak type epoxy resins, cresol novolak type epoxy resins, biphenyl type epoxy resins, triphenol alkane type epoxy resins, heteroglycidic epoxy resins, bisphenol A type epoxy resins, bisphenol F type epoxy resins, and naphthalene ring-containing type epoxy resins.

10. The composition of claim 9, in which said epoxy resin and said polyimide are present at a ratio of about 20:80 to about 80:20 wt %.

11. The composition of claim 9, in which 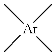
is selected from the group consisting of:

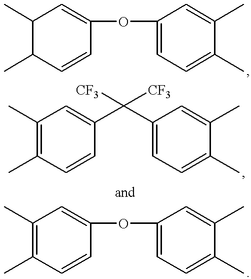

12. An epoxy/polyimide composite, which has a repeating unit selected from the group consisting of: 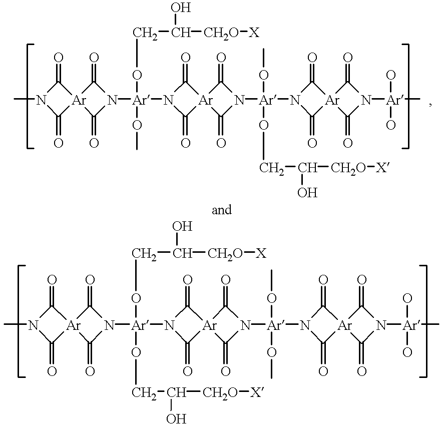
wherein 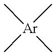
is an aromatic group selected from the group consisting of: 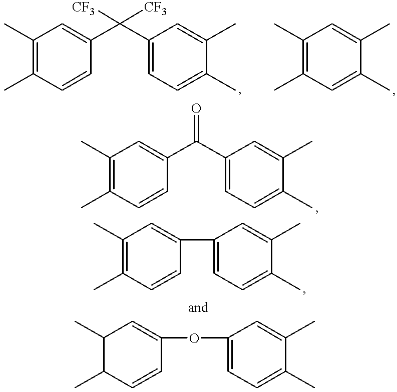 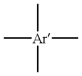
is an aromatic group of the general formula: 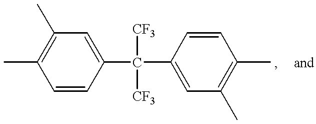
X and X′ are independently an epoxy moiety.

13. The composite of claim 12, in which 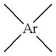
is

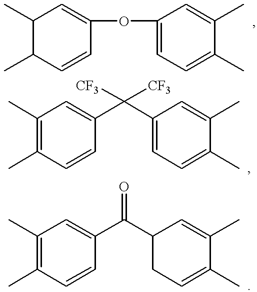

14. The composite of claim 12, in which said epoxy moiety is derived from epoxy resins selected from the group consisting of novolak type epoxy resins, cresol novolak type epoxy resins, biphenyl type epoxy resins, triphenol alkane type epoxy resins, heteroglycidic epoxy resins, bisphenol A type epoxy resins, bisphenol F type epoxy resins, and naphthalene ring-containing type epoxy resins.

15. The composite of claim 14, in which said epoxy moiety is derived from epoxy resins selected from the group consisting of:

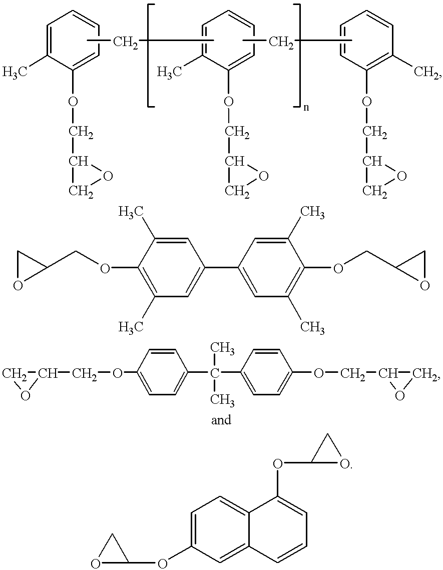

16. A process of preparing a polyimide of claim 1, comprising the steps of:
(a) providing a solution of diamine in an organic solvent;
(b) adding dianhydride monomers with functional groups to the solution of step (a);
(c) incubating the resulting mixture to form polyamic acid; and
(d) converting said polyamic acid to polyamide by thermal imidization.

17. The process of claim 16, in which the step (c) further comprises the step of precipitating said polyamic acid in an aqueous solvent; and evaporating the solvent to give a powder form of polyamic acid.

18. The process of claim 16, in which said diamine is represented by the general formula: 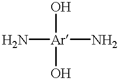
wherein 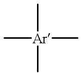
is defined as in claim 1.

19. The process of claim 16, wherein said organic solvent is selected from the group consisting of N-methylpyrrollidone, acetone, N,N-dimethyl acetamide, and dimethylformainide.

20. The process of claim 16, wherein said polyamic acid is represented by the general formula: 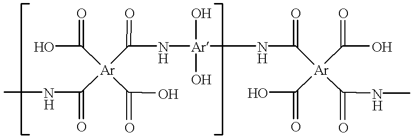
wherein 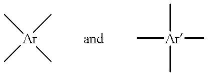
are defined as claim 1.

21. A process of preparing an epoxide/polyimide composite of claim 12, comprising the steps of:
(a) providing a solution of diamine in an organic solvent;
(b) adding dianhydride monomers with functional groups to the solution of step (a);
(c) incubating the resulting mixture to form polyamic acid in the form of a liquid;
(d) converting said liquid polyamic acid to polyamic acid in the form of a powder;
(e) converting said powder polyamic acid to polyamide;
(f) providing a solution of an epoxy resin in an organic solvent;
(g) mixing the solution of the step (f) and said polyamide of the step (e); and
(h) curing the resulting mixture to obtain the epoxy/polyimide composite.

22. The process of claim 21, in which said polyamide of the step (g) is in the form of a podwer.

23. The process of claim 21, in which said diamine is represented by the general formula: 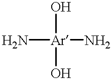
wherein 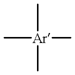
is defined as in claim 1.

24. The process of claim 21, wherein said organic solvent in the steps (a) and (f) is selected from the group consisting of N-methylpyrrollidone, acetone, N,N-dimethyl acetamide, and dimethylformamide.

25. The composite of claim 21, in which said epoxy resin is selected from the group consisting of novolak type epoxy resins, cresol novolak type epoxy resins, biphenyl type epoxy resins, triphenol alkane type epoxy resins, heteroglycidic epoxy resins, bisphenol A type epoxy resins, bisphenol F type epoxy resins, and naphthalene ring-containing type epoxy resins.

26. A process of encapsulating electronic parts, which comprises the steps of applying the composition of claim 6 onto said parts; and curing said composition.
